(19) United States
(12) Patent Application Publication
(10) Pub. No.: US 2007/0290302 A1
(43) Pub. Date: Dec. 20, 2007

(54) IC chip package, and image display apparatus using same

(75) Inventors: Tomokatsu Nakagawa, Hiroshima (JP); Yasunori Chikawa, Hiroshima (JP); Setsunobu Wakamoto, Shiki-gun (JP); Tatsuya Katoh, Kasaoka-shi (JP); Satoru Kudose, Fukuyama-shi (JP)

Correspondence Address: HARNESS, DICKEY & PIERCE, P.L.C., P.O. BOX 8910, RESTON, VA, 20195, US

(73) Assignee: Sharp Kabushiki Kaisha

(21) Appl. No.: 11/808,834

(22) Filed: Jun. 13, 2007

(30) Foreign Application Priority Data
Jun. 14, 2006 (JP) 2006-165257

(51) Int. Cl. H01L 23/495

(52) U.S. Cl. 257/668; 257/E23.034

(57) ABSTRACT

In a liquid crystal driver package (1a) of one embodiment of the present invention, a film base member (2) is connected to a liquid crystal driver (3) through an interposer substrate (4a). Film base member connecting terminals (13) of the interposer substrate (4a) are connected to terminals of on-film wires (5 and 6) of the film base member (2) with an anisotropic conductive adhesive. An insulating film (7) is formed at an edge section of the interposer substrate (4a) and a periphery section of the edge section. This arrangement prevents the on-film wires (5 and 6) from coming into direct contact with the interposer substrate (4a). Therefore, it becomes possible to provide an IC chip (liquid crystal driver) package in which short circuit does not occur between the on-film wires adjacent to each other.

This Nonprovisional application claims priority under 35 U.S.C. §119(a) on Patent Application No. 165257/2006 filed in Japan on Jun. 14, 2006, the entire contents of which are hereby incorporated by reference.

### FIELD OF THE INVENTION

The present invention relates to an IC chip package including, for example, finely pitched terminals, and an image display apparatus including the IC chip package.

### BACKGROUND OF THE INVENTION

With the development of a liquid crystal display apparatus with high definition and high performance, a liquid crystal driver (IC chip) incorporated in the liquid crystal display apparatus is required to have an increased number of outputs.

Generally, the increased number of outputs in an IC chip is realized by a reduced chip size, a finer pitch (smaller pitch) of bumps provided in a chip, or the like. Recently, a COF (Chip On Film) is often used. The COF can realize the fine pitch and includes a bare chip liquid crystal driver.

In the latest COF package, inner leads on a tape carrier are bonded to bumps on an IC chip by the application of heat and pressure so that the tape carrier is brought into conduction with the IC chip. However, such a bonding method requires a very fine tape carrier material which is less susceptible to heat deformation to prevent misalignment between bumps and inner leads. In other words, the realization of a fine pitch limits a choice of a material for a tape carrier.

As a method of solving such a problem, Patent Document 1 (Japanese Unexamined Patent Publication No. 2004-207566 (Tokukai 2004-207566) (published on Jul. 22, 2004)) discloses a method in which an IC chip is connected to a circuit board (tape carrier) through an interposer substrate. FIG. 18 illustrates a cross sectional view of a package structure described in Patent Document 1.

As illustrated in FIG. 18, an IC chip 104 is connected to an interposer substrate 101 by flip chip bonding. The interposer substrate 101 is further connected to a terminal pattern 110 of a circuit board 107 by bump bonding. The interposer substrate 101 is a silicon (Si) substrate and formed in a Si wafer process. This makes it possible to form terminals of the interposer substrate 101 which terminals are connected to the terminals of the IC chip 104, at a pitch as fine as that of the terminals of the IC chip 104. On the other hand, terminals of the interposer substrate 101 which terminals are connected to the circuit board 107 are formed at a pitch that agrees with a pitch of the terminals of the circuit board 107, which pitch is relatively large. The terminals connected to the IC chip 104 are connected to the corresponding terminals connected to the circuit board 107 on the interposer substrate 101. As the circuit board 107, a tape carrier can be used.

In other words, the interposition of the interposer substrate 101 as illustrated in FIG. 18 allows a fine pitch of the IC process to be changed to a terminal pitch of the tape carrier. Therefore, the limitation to a choice of tape carrier materials is eased even with the use of a COF package in which an IC chip whose connecting terminals are provided at a very fine pitch is included for reduced size or increased outputs of the IC chip.

In order to connect the IC chip 104 and the interposer substrate 101, metal or metal alloy bumps which have a relatively high hardness and a high fusing point is employed for a fine pitch. For example, such connection is realized by Au—Au bonding using Au bumps. This makes it possible to suppress deformation of bumps and solve a problem in that a bump contacts another adjacent bump. Consequently, a terminal pitch can be reduced up to approximately 25 μm. As a result, the number of outputs of an IC chip can be increased.

Meanwhile, the connection between the interposer and the tape carrier can be connection between terminals which are spaced at a pitch, for example, at a pitch of approximately 50 μm to 100 μm. The pitch is larger than a pitch of the terminals for the connection between the IC chip and the interposer. This eliminates the need for expensive connecting terminals such as Au bumps. In addition, the connection can be realized by group bonding with the use of an ACF (Anisotropic Conductive Film) or an ACP (Anisotropic Conductive Paste).

Moreover, application of such ACF/ACP bonding eliminates the need for protruding terminals as connecting terminals. This holds promise of simplifying a production process of the interposer substrate.

However, the structure illustrated in FIG. 18 has the problem that quality defect of an IC chip package may occur when a Si or the like interposer substrate is connected to a tape carrier by ACF bonding or the like. The following specifically explains the defective quality defect of an IC chip package.

FIG. 19 is a cross sectional view illustrating an interposer substrate 201 which is connected to a tape carrier 207 and on which an IC chip 204 is mounted. The tape carrier 207 used in COF is made of a material that is thin and highly flexible so that the material can be easily bent. The interposer substrate 201 is one of pieces into which a Si wafer is separated by dicing or scribing in a Si wafer process. A conductive Si substrate is exposed at edge sections of the interposer substrate 201. When the interposer substrate 201 having such a structure is connected to the tape carrier 207 by ACF bonding 205, the edge section of the interposer substrate 201 where a conductive Si substrate is exposed touches wiring terminals 210 on the tape carrier 207 (at P shown in FIG. 19). This causes a short circuit between wiring terminals on the tape carrier 207, thus leading to an IC chip package with a quality defect.

This significantly deteriorates reliability of an image display apparatus including an IC chip package having such a structure.

### SUMMARY OF THE INVENTION

The present invention is attained in view of the problems mentioned above. An object of the present invention is to provide (i) a high quality IC chip package in which a short circuit does not occur between wires even in a case where a wire of a tape carrier which is connected to an interposer substrate touches an edge section of the interposer substrate, and (ii) an image display apparatus including the IC chip package.

An IC chip package of the present invention, in order to solve the problem mentioned above, includes: an IC chip; an interposer substrate including wiring conductors each having an IC chip connecting terminal and a tape carrier connecting terminal; and a tape carrier including wiring conductors each having an interposer substrate connecting terminal to be connected to the tape carrier connecting terminal by conductive connection, wherein: the tape carrier connecting terminal is connected with an anisotropic conductive adhesive to the interposer substrate connecting terminal to form conductive connection; and the interposer substrate has an insulating section at an edge section thereof.

As mentioned above, the interposer substrate includes an insulating section at an edge section thereof. In an arrangement where the interposer substrate is connected with an anisotropic conductive adhesive such as an ACF or an ACP to a tape carrier which is made of a thin and highly flexible material so that the tape carrier is easily bent, a wire of the tape carrier may touch the edge section of the interposer substrate. Even in such a case, the occurrence of a short circuit in the wiring conductor of the tape carrier can be prevented. As a result, it is possible to maintain a desired quality of an IC chip package without the occurrence of quality defect.

Moreover, with the provision of the insulating section, the ACF bonding as mentioned above can be adopted without difficulty. Thus, it is possible to reduce cost for package production while realizing a package of a desired quality for the following reasons. That is, because the ACF bonding is a process performed under a low temperature and simultaneously completes resin sealing and the bonding, it becomes possible to realize a short processing time and a high productivity. Moreover, since the ACF bonding eliminates the need for a protruding terminal as a connection terminal, a production process of the interposer substrate can be simplified.

It is preferable that position where the insulating section is provided includes a region where (i) no problem occurs when electrically connecting the tape carrier connecting terminals with the interposer substrate connecting terminals on the tape carrier and (ii) the interposer substrate is likely to touch an on-tape wiring conductors of the tape carrier if it is left exposed. Specifically, it is preferable that the region includes at least a part of a region that is on a surface of the interposer substrate and faces the wiring conductors of the tape carrier. More specifically, it is preferable that the region includes at least a part of a region that is on an edge surface of the interposer substrate, an edge section of the interposer substrate, and a surface extending from the edge section to the tape carrier connecting terminals on the interposer substrate.

In the IC chip package of the present invention, the tape carrier is made of a flexible material. Moreover, the present invention includes a structure that the wiring conductors of the tape carrier touch the insulating section.

Specifically, in the IC chip package of the present invention, it is preferable that an insulating film is provided as the insulating section.

This makes it possible to employ a general-purpose semiconductor substrate made of silicon or the like as an interposer substrate.

In the IC chip package of the present invention, it is preferable that the interposer substrate is an insulating substrate. In this arrangement, a part of the insulating substrate serves as the insulating section.

According to the arrangement, the entire interposer substrate has an insulating property. This makes it possible to simplify a production process of the interposer substrate, compared with the arrangement in which an insulating material is formed only at an edge section of the interposer substrate.

In the IC chip package of the present invention, it is preferable that the interposer substrate is made of a material having a property of transmitting visible light.

According to the arrangement, it becomes easy to check an alignment in flip chip bonding of the IC chip.

In other words, in the case of flip chip bonding, an IC chip is mounted on the interposer substrate so that an IC chip surface having input/output terminals faces an interposer substrate surface having IC chip connecting terminals. In this case, the input/output terminals and the IC chip connecting terminals are sandwiched between the IC chip and the interposer substrate and cannot be seen externally. Therefore, it becomes difficult for a producer to check a connecting condition of these terminals. On the contrary, in the IC chip package of the present invention, the interposer substrate is made of a material that has a property of transmitting visible light. Therefore, it becomes easy for a producer or an apparatus capable of checking the connecting condition to check the connecting condition from a surface of the interposer substrate opposite to the surface on which the IC chip is mounted.

In the IC chip package of the present invention, the anisotropic conductive adhesive can employ an anisotropic film obtained by forming thermosetting resin in which conductive particles are mixed so that the thermosetting resin is in film form, or an anisotropic conductive paste obtained by forming thermosetting resin in which conductive particles are mixed so that the thermosetting resin is in paste form.

As mentioned above, an anisotropic conductive film (ACF) or an anisotropic conductive paste (ACP) is used as the anisotropic conductive adhesive. The tape carrier connecting terminals of the interposer substrate and the interposer substrate connecting terminals of the tape carrier between which the ACF or ACP is sandwiched are heated and pressed. This allows the terminals to be electrically connected via the conductive particles sandwiched by the terminals. At the same time, the thermosetting resin serves as a binder between the terminals to connect the terminals to each other.

The conductive particles mixed in the resin are dispersed in a lateral direction. However, because the resin includes thermosetting resin, the thermosetting resin ensures insulation between the terminals adjacent to each other.

Moreover, the thermosetting resin protects the conductive particles from an external environment. This prevents deterioration of the conductive particles due to oxidation or the like.

An IC chip package of the present invention includes: an IC chip; an interposer substrate including wiring conductors each having an IC chip connecting terminal and a tape carrier connecting terminal; and a tape carrier including wiring conductors each having an interposer substrate connecting terminal to be connected to the tape carrier connecting terminal by conductive connection, wherein: the interposer substrate is a semiconductor substrate; and the interposer substrate has an insulating section at an edge section thereof.

As mentioned above, the insulating section is provided at an edge section of the interposer substrate made of a semiconductor material such as silicon. Accordingly, in a case where the interposer substrate is connected to the tape carrier, the occurrence of a short circuit between the wiring conductors of the tape carrier can be prevented even if the wire of the tape carrier touches the edge section of the interposer substrate. As a result, it is possible to maintain a desired quality of an IC chip package without the occurrence of quality defect. This arrangement is applicable not only in a case where bonding with an anisotropic conductive adhesive such as an ACF or an ACP is adopted but also in a case where bonding other than the bonding with an anisotropic conductive adhesive is adopted. A preferable position of the insulating section is the same as mentioned above.

In the IC chip package of the present invention, the IC chip can be a driver IC for driving an image display that operates under an electrical signal.

An image forming apparatus of the present invention includes: an IC chip package including the IC chip that is a driver IC for driving an image display that operates under an electrical signal; and an image display that operates under an electrical signal.

According to an arrangement as mentioned above, an image display apparatus can include a high quality IC chip package that has multiple outputs and does not cause a short circuit between the wiring conductors. Accordingly, it is possible to provide a highly reliable image display apparatus with high definition and high performance.

For a fuller understanding of the nature and advantages of the invention, reference should be made to the ensuing detailed description taken in conjunction with the accompanying drawings.

### BRIEF DESCRIPTION OF THE DRAWINGS

FIG. 1 is a plan view illustrating the structure of a liquid crystal driver package in accordance with embodiment 1 of the present invention.

FIG. 2 is a cross sectional view of the liquid crystal driver package taken along line A-A′ of FIG. 1.

FIG. 3 is an oblique perspective view illustrating an arrangement of the liquid crystal driver and an interposer substrate for the liquid crystal driver package shown in FIG. 1.

FIG. 4 is a cross sectional view illustrating a state in which on-film wires of the liquid crystal driver package shown in FIG. 1 are in contact with an insulating film.

FIG. 5 is an explanatory diagram of a production method of the liquid crystal driver package shown in FIG. 1.

FIG. 6 is an explanatory diagram of a production method of the liquid crystal driver package shown in FIG. 1.

FIG. 7 is a cross sectional view illustrating another structure of the liquid crystal driver package shown in FIG. 1.

FIG. 8 is an explanatory diagram of a production method of the liquid crystal driver package shown in FIG. 1.

FIG. 9 is an explanatory diagram of a production method of the liquid crystal driver package shown in FIG. 1.

FIG. 10 is a diagram illustrating an arrangement of a liquid crystal driver mounted display apparatus including the liquid crystal driver package shown in FIG. 1.

FIG. 11 is an oblique perspective view illustrating another arrangement of an interposer substrate for the liquid crystal driver package shown in FIG. 1.

FIG. 12 is an oblique perspective view illustrating still another arrangement of an interposer substrate for the liquid crystal driver package shown in FIG. 1.

FIG. 13 is an oblique view illustrating yet another arrangement of an interposer substrate for the liquid crystal driver package shown in FIG. 1.

FIG. 14 is an oblique perspective view illustrating another arrangement of an interposer substrate for the liquid crystal driver package shown in FIG. 1.

FIG. 15 is an oblique view illustrating still another arrangement of an interposer substrate for the liquid crystal driver package shown in FIG. 1.

FIG. 16 is an oblique view illustrating yet another arrangement of an interposer substrate and a liquid crystal driver for the liquid crystal driver package shown in FIG. 1.

FIG. 17 is a cross sectional diagram illustrating the structure of a liquid crystal driver package in accordance with another embodiment of the present invention.

FIG. 18 is a cross sectional view illustrating an IC chip package structure in relation to conventional art.

FIG. 19 is an explanatory cross sectional view illustrating a problem that occurs in the structure shown in FIG. 18.

### DESCRIPTION OF THE EMBODIMENTS

### Embodiment 1

The following will describe an embodiment of a liquid crystal driver package (IC chip package) in accordance with the present invention. The following description includes various limitations. These are technically preferred in the implementation of the present invention, but by no means limiting the scope of the present invention.

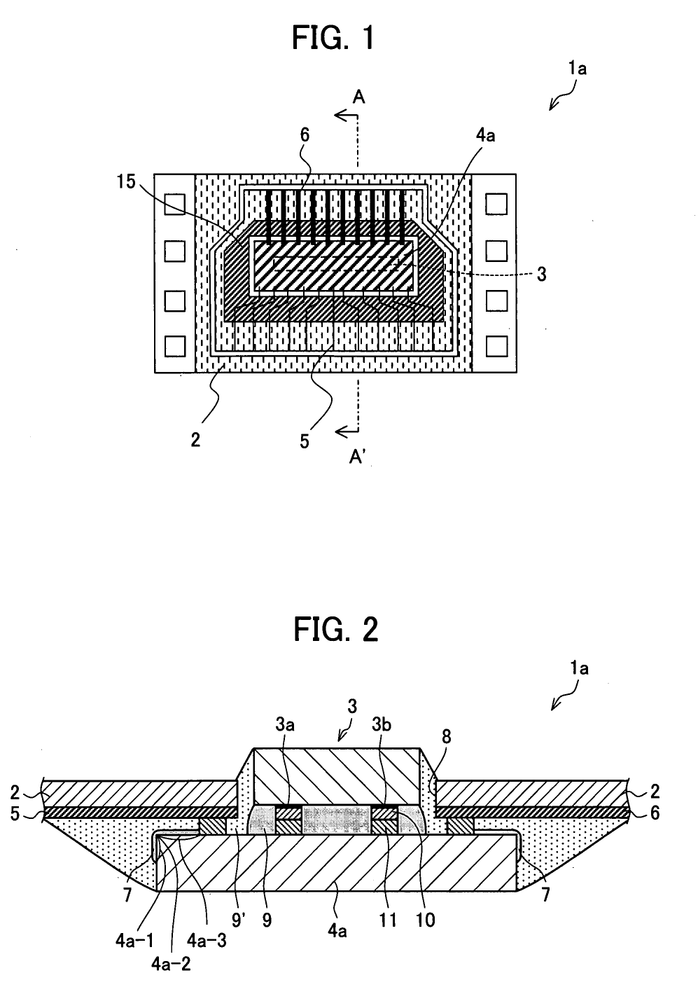

First, with reference to FIGS. 1 through 16, a liquid crystal driver package will be described in accordance with the present invention.

FIG. 1 is a plan view illustrating a structure of a liquid crystal driver package in accordance with the present embodiment, the plan view illustrating the liquid crystal driver package viewed from a side where an interposer substrate 4a is provided. FIG. 2 is a cross sectional view of the liquid crystal driver package 1a taken along line A-A′ of FIG. 1. For convenience, FIG. 2 illustrates a part of a cross section taken along the line A-A′, with the interposer substrate 4a facing downward of FIG. 2.

A liquid crystal driver package 1a of the present embodiment can be used as a liquid crystal display drive device which is provided adjacent to a liquid crystal display with a display surface on the periphery of the display surface so that the liquid crystal display is driven. To this end, the liquid crystal driver package 1a, as shown in FIG. 1, includes a film base member (tape carrier) 2, a liquid crystal driver (IC chip) 3, an interposer substrate 4a. In the liquid crystal driver package 1a, as shown in FIG. 2, the liquid crystal driver 3 is provided in a device hole 8 of the film base member 2. The liquid crystal driver 3 is supported by the film base member 2 via the interposer substrate 4a. The present embodiment explains a liquid crystal driver package in the form of a COF. In the COF, wiring conductors (inner leads) formed on the film base member 2 face wiring conductors formed on the interposer substrate 4a.

The liquid crystal driver 3 includes a plurality of liquid crystal drive circuits (not shown) and drives a liquid crystal display. As shown in FIG. 2, each of the liquid crystal drive circuits includes drive signal output terminals 3a via which respective drive signals are outputted and signal input terminals 3b via which image data signal and other signals are respectively inputted. The liquid crystal driver 3, to be mounted to the liquid crystal driver package 1a of the present embodiment, may have a chip size of, for example, 1 mm×8 mm. The liquid crystal driver 3 may also be thin-layered by polishing a chip.

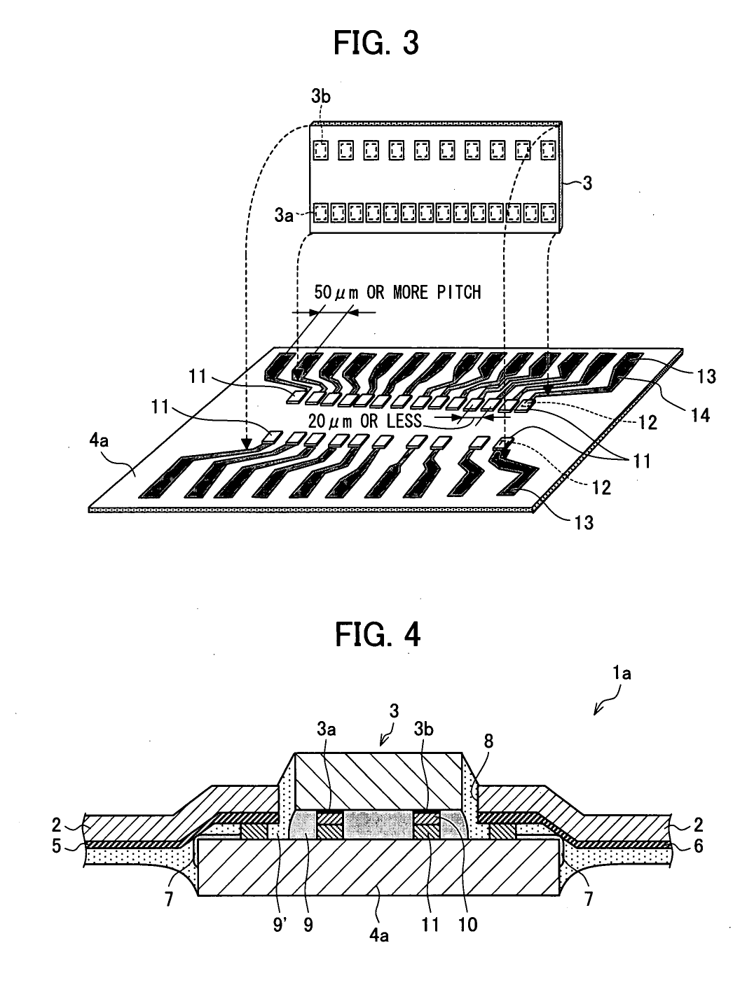

The interposer substrate 4a can be made of a semiconductor material, preferably, silicon. Size of the interposer substrate 4a is not specifically limited. For example, the interposer substrate 4a may have a size of 2 mm×20 mm and a thickness of 400 μm. With reference to FIG. 3, an arrangement of the interposer substrate 4a is explained in details.

FIG. 3 is an oblique perspective view of an arrangement of the interposer substrate 4a to be provided with the liquid crystal driver 3.

As shown in FIG. 3, the interposer substrate 4a includes on one surface thereof liquid crystal driver connecting terminals (IC chip connecting terminals) 12, film base member connecting terminals (tape carrier connecting terminals) 13, and on-substrate wires (on-substrate wiring conductors) 14. The on-substrate wires 14 connect the liquid crystal driver connecting terminals 12 to the film base member connecting terminals 13. Specifically, as shown in FIG. 3, the liquid crystal driver connecting terminals 12 are provided near the center of the interposer substrate 4a and the film base member connecting terminals 13 are provided, outside the liquid crystal driver connecting terminals 12, on the periphery.

The liquid crystal driver connecting terminals 12 are connected to the drive signal output terminals 3a and the drive signal input terminals 3b by bump bonding, respectively. To this end, bumps 11 are provided on the liquid crystal driver connecting terminals 12. Bumps 10 are provided on the drive signal output terminals 3a and the drive signal input terminals 3b, respectively. The following is a specific connecting method. Namely, in a case where gold bumps are used as the bumps, for example, the interposer substrate 4a and the liquid crystal driver 3 are heated up to approximately 430° C., and then the bumps 10 and 11 are connected to each other by applying pressure to the interposing substrate 4a and the liquid crystal driver 3. This allows the interposer substrate 4a and the liquid crystal driver 3 to be electrically connected.

As to heights of the bumps 10 and 11, the height of the bump 11 formed on the liquid crystal driver connecting terminal 12 may be, for example, 7.5 μm, and the height of the bump 10 may be 7.5 μm. Thus, the total height of the bumps 10 and 11 may become 15 μm.

A pitch between the drive signal output terminals 3a and a pitch between the drive signal input terminals 3b (a pitch between the bumps 10) are fine pitches from more than 0 μm to equal to or less than 20 μm, respectively. Correspondingly, the bumps 11 also have a fine pitch of 20 μm or less.

As mentioned above, gold bumps that can be processed in a semiconductor process may be employed as the bumps 10 and 11. However, the present invention is not limited to the gold bumps. Any conductive material may be employed as the bumps 10 and 11, provided that the bumps 10 and 11 can be fabricated in a semiconductor process. By employing a bump material that can be fabricated in a semiconductor process, a finer bump pitch can be realized along with progress in a finer semiconductor process. In other words, if the gold bumps formed on the terminals of the liquid crystal driver 3 can be positioned so as to face the liquid crystal driver connecting terminals 12 of the interposer substrate 4a, the connection between the bumps 10 and 11 becomes possible at wiring intervals processed in the semiconductor process.

The film base member connecting terminals 13 are connected to terminals (interposer substrate connecting terminals) of on-film wires 5 and 6 provided on the periphery of the device hole 8 of the film base member 2. The film base member connecting terminals 13 is formed to have a pitch larger than the pitch of the liquid crystal driver connecting terminals 12. Specifically, the pitch of the film base member connecting terminals 13 is equal to 50 μm or more.

In this way, on the interposer substrate 4a, the pitch of the film base member connecting terminals 13 is formed to be larger than the pitch of the liquid crystal driver connecting terminals 12. The provision of the interposer substrate 4a eliminates the necessity of making the on-film wires 5 and 6 of the film base member 2 become finely pitched even in a case where the terminals of the liquid crystal driver 3 are finely pitched. Accordingly, it is possible to form, with an existing technique, the on-film wires 5 and 6 of the film base member 2 without (i) any technical innovation such as reduction in a thickness of a copper foil and (ii) any equipment such as a new processing machine for accommodating the technical innovation. This allows significant suppression of increase in cost.

In other words, the provision of the interposer substrate 4a allows the terminals of the liquid crystal driver 3 to be as finely pitched as possible without consideration of the pitch between the terminals of the film base member 2. This makes it possible to reduce chip size of the liquid crystal driver 3. Consequently, cost reduction can be realized. Specifically, it becomes possible to carry out mounting of a liquid crystal driver with 520 or more bumps, which liquid crystal driver has a chip size of 1 mm×8 mm and a pad pitch of 20 μm.

In this embodiment, the bumps are provided on the liquid crystal driver connecting terminals 12 of the interposer substrate 4a, and the drive signal output terminals 3a and the drive signal input terminals 3b of the liquid crystal driver 3, respectively. However, the present invention is not limited to this arrangement. Alternatively, the bumps each having a height of 15 μm may be formed either on the liquid crystal driver connecting terminals 12 of the interposer substrate 4a, or on the drive signal output terminals 3a and the drive signal input terminals 3b of the liquid crystal driver 3.

The present embodiment explains an arrangement in which one liquid crystal driver 3 is mounted on one interposer substrate 4a. However, the present invention is not limited to this arrangement. Alternatively, a plurality of liquid crystal drivers may be mounted on one interposer substrate 4a.

The film base member connecting terminals 13 and the terminals of the on-film wires 5 and 6 are connected not by bump bonding but by group bonding with the use of an anisotropic conductive adhesive material, namely, an ACF or an ACP. Compared with a connection by bump bonding, this makes it possible to simplify a bump forming process. The group bonding also makes it possible to minimize (i) a distance between a film base member connecting terminal 13 and a terminal of the on-film wire 5 and (ii) a distance between a film base member connecting terminal 13 and a terminal of the on-film wire 6. The ACF is obtained by forming a thermosetting resin in which conductive particles are mixed so that the thermosetting resin has a film shape. The ACP is a paste resin to which conductive particles are mixed. The terminals between which the ACF or ACP is sandwiched are heated and pressed. This allows the terminals to be electrically connected via the conductive particles. At the same time, the thermosetting resin serves as a binder between the terminals. The ACF has an equivalent behavior to that of the ACP. It is possible to select either one of them according to how such resin is provided on the terminals. Specifically, an ACF will be used when a process of pasting is carried out, whereas an ACP will be used when a process of printing or application is carried out.

The on-film wires 5 and 6 formed on the film base member 2 are connected to the film base member connecting terminals 13. This allows the on-film wires 5 and 6 to be electrically connected to an integrated circuit (not shown) of the liquid crystal driver 3, through the interposer substrate 4a. Specifically, the on-film wire 5 is an output wire for transmitting, to a liquid crystal display, a signal (such as a drive signal) outputted from the liquid crystal driver 3. The on-film wire 6 is an input wire for inputting a control signal (such as an image data signal) into the liquid crystal driver 3. As illustrated in FIG. 1, it is preferable that solder resist 15 is provided on the surfaces of the on-film wires 5 and 6 so that the on-film wires 5 and 6 are protected.

The film base member 2 is formed by a highly flexible material such as an organic film, for example, polyimide (PI) or polyethylene terephthalate (PET) so that the film base member can be easily bent.

In a case where the film base member 2 is formed with such a material, the on-film wires 5 and 6 each may touch an edge section of an interposer substrate and/or a periphery section thereof, as illustrated in FIG. 19. As explained later, in a production process of an interposer substrate, respective interposer substrates are separated from a wafer by dicing or scribing. Accordingly, a conductive Si substrate is exposed at edge sections of the substrate. When an interposer substrate 201 exposes a Si substrate thereof as illustrated in FIG. 19, a short circuit may occur between wiring terminals due to a contact of the wiring terminal 210 with an edge surface and/or the edge section of the interposer substrate 201. However, in the liquid crystal driver package 1a of the present embodiment, as illustrated in FIG. 4, an insulating film 7 is provided at an edge section of the interposer substrate 4a and on an periphery section of the edge section. This makes it possible to prevent the on-film wires 5 and 6 from directly touching the interposer substrate 4a.

Since the present invention includes a highly flexible film base member 2, the present invention can include a liquid crystal driver package having an arrangement in which the on-film wires 5 and 6 are brought into contact with the insulating film 7 due to an externally applied load during and after the production of the liquid crystal driver package.

Explained below is an insulating film 7.

As illustrated in FIG. 2, the insulating film 7 is provided at the edge section of the interposer substrate 4a and on the periphery section of the interposer substrate 4a. The “periphery section” here indicates a region where (i) no problem occurs when electrically connecting the film base member connecting terminals 13 with the terminals of the on-film wires 5 and 6 and (ii) the interposer substrate 4a is likely to touch the on-film wires 5 and 6 if it is left exposed. Specifically, the “periphery section” indicates a region that is on a surface of the interposer substrate 4a and faces the on-film wires 5 and 6. More specifically, as illustrated in FIG. 2, the insulating film 7 is provided on an edge surface 4a-1 of the interposer substrate 4a, an edge section 4a-2 of the interposer substrate 4a, and a surface 4a-3 extending from the edge section to the film base member connecting terminals 13 on the interposer substrate 4a.

The insulating film 7 may be made of, for example, epoxy resin or acryl resin. A thickness of the insulating film 7 is not specifically limited if the insulating film can insulate the on-film wires 5 and 6 from the interposer substrate 4a. The thickness of the insulating film 7 may be, for example, 2 μm to 6 μm.

Next, the following description deals with how the insulating film 7 is provided on the edge section of the interposer substrate 4a and the periphery section of the edge section together with a production process of the liquid crystal driver package 1a of the present embodiment.

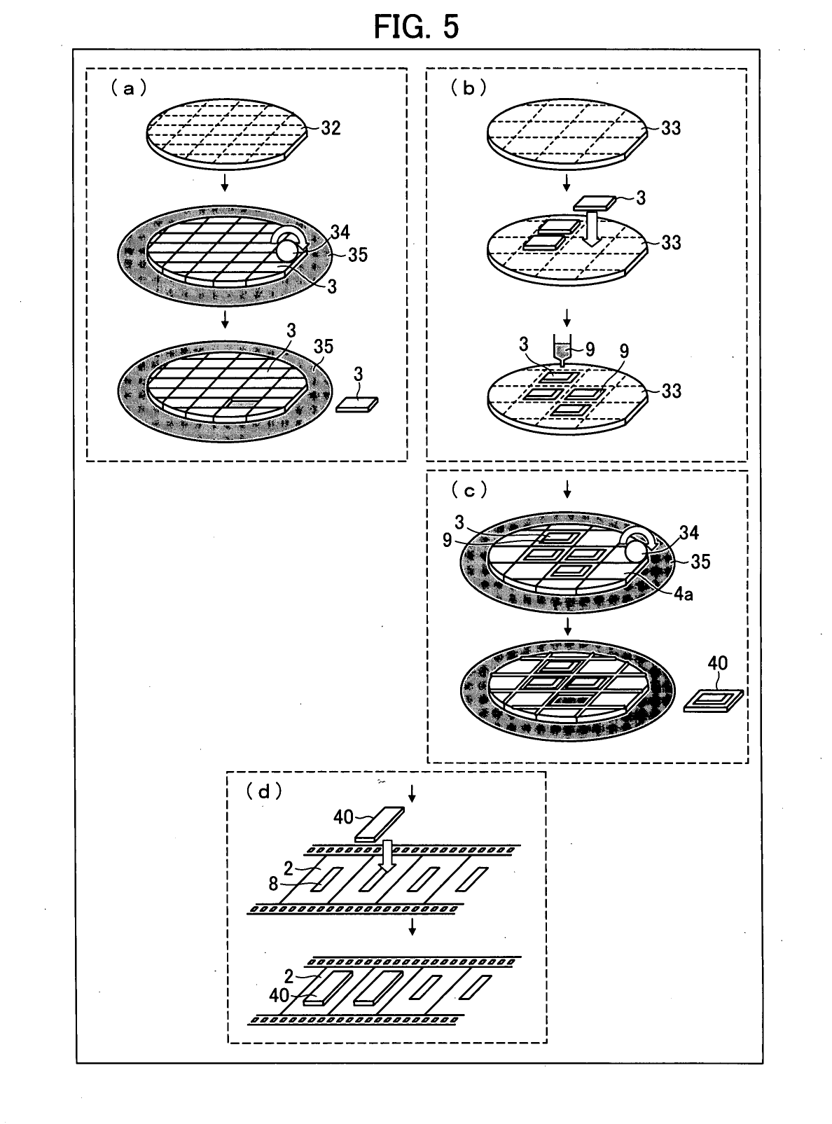

FIG. 5 is an explanatory diagram illustrating how the liquid crystal driver package 1a is produced.

First, a driver wafer 32, on which liquid crystal drive circuits or the like are patterned to form liquid crystal drivers, is separated by dicing into individual liquid crystal drivers 3 (See (a) surrounded by the dotted line in FIG. 5). A conventional dicing can be used. For example, a driver wafer 32 may be mounted on a mounting platform 35 and diced by a dicing blade 34 into individual chips having a predetermined chip size.

Secondly, the driver 3 is connected to an interposer wafer 33 on which the liquid crystal driver connecting terminals 12, the film base member connecting terminals 13, and the on-base wires 14 are patterned. The connection is made by bump bonding with the use of the bumps 10 and 11 (See FIG. 2) that are formed beforehand. After the connection, a space between the liquid crystal driver 3 and the interposer wafer 33 that are connected to each other is sealed by a sealant 9 such as resist or resin (See (b) surrounded by the dotted line (b) in FIG. 5.). This sealing of the space with the sealant 9 can prevent silicon swarf to be produced during a subsequent process of dicing the interposer wafer from entering the space. This sealing with the sealant 9 does not need to entirely cover the liquid crystal driver 3. Alternatively, the sealing of only the space between the liquid crystal driver 3 and the interposer wafer 33 with the sealant 9 is sufficient.

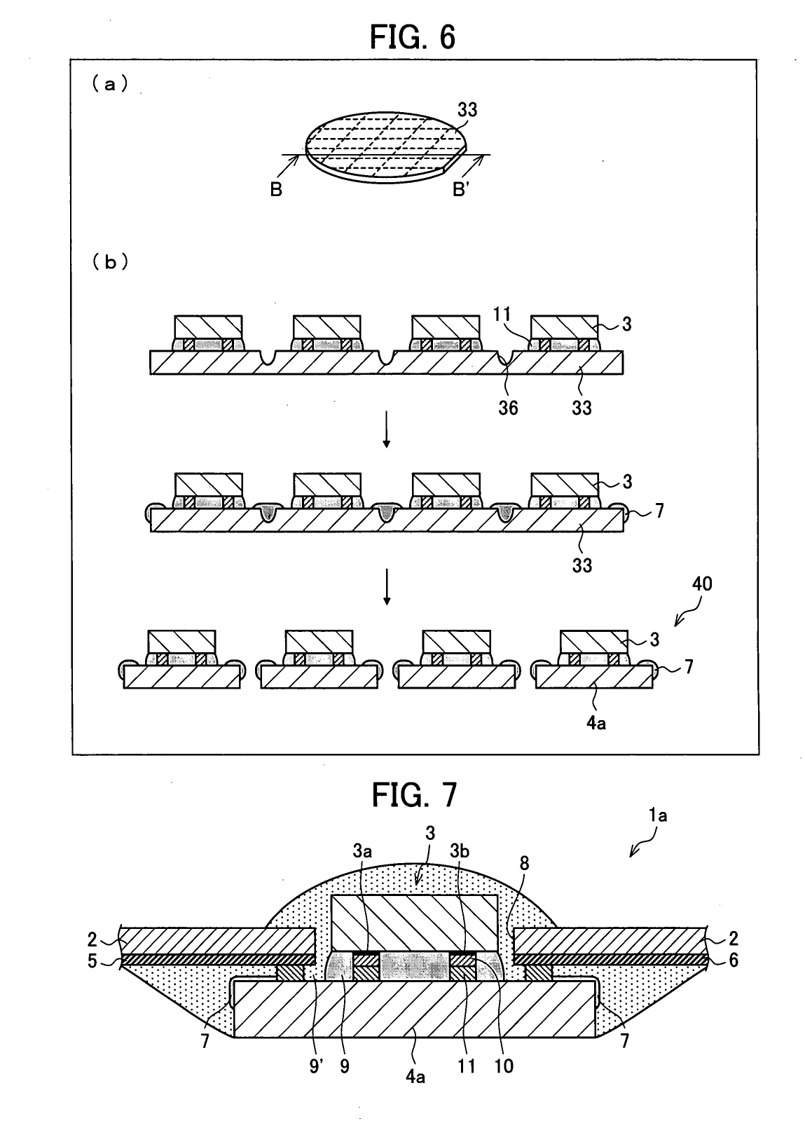

Here, a process of dicing an interposer wafer is explained in details, with reference to FIGS. 6(a) and 6(b).

FIG. 6(a) is an oblique perspective view illustrating an interposer wafer 33 to which a liquid crystal driver 3 is connected (hereinafter, simply referred to as an interposer wafer 33). FIG. 6(b) is a cross sectional view illustrating a cross section of the interposer wafer 33 shown in FIG. 6(a) taken along line B-B′ and illustrates how the interposer wafer 33 is separated into individual interposer substrates by dicing.

In this embodiment, when the interposer wafer 33 shown in FIG. 6(a) is diced with the dicing blade 34 (See (c) surrounded by the dotted line in FIG. 5), the dicing with respect to the interposer wafer 33 is stopped in the middle, specifically, at a half thickness of the interposer wafer 33. This causes a groove 36 to be formed on the surface of the wafer 33 (See a top figure of FIG. 6(b)).

Then, an insulating material, such as epoxy resin or acryl resin to become an insulating film 7, is applied to the groove 36 and a periphery section thereof (See a middle figure of FIG. 6(c)). A method of applying the insulating material may employ a conventional method such as a printing method.

After application of the insulating material to the groove 36 and the periphery section thereof, the insulating material is hardened by use of heat or light. Then, the dicing is resumed to separate the interposer wafer 33 into individual interposer substrates. As a result, a liquid crystal driver mounted interposer substrate 40 can be obtained. Thus obtained liquid crystal driver mounted interposer substrate 40 includes the insulating film 7 at the edge section and on the periphery section of the edge section (See a bottom figure of FIG. 6(b), and the drawing (c) surrounded by the dotted line in FIG. 5).

The liquid crystal driver mounted interposer substrate 40 is positioned so that the liquid crystal driver 3 is disposed in a device hole 8 of the film base member 2. Then, the terminals of the on-film wires 5 and 6 of the film base member 2 are connected to the film base member connecting terminals 13 with the use of an ACF or an ACP. At the end, the liquid crystal driver mounted interposer substrate 40 is sealed together with the on-film wires 5 and 6 of the film base member 2 with a sealant 9′ such as resin. As a result, a COF liquid crystal driver package 1a as illustrated in FIG. 2 is obtained. The sealant 9′ does not need to seal the entire interposer substrate 4a at the sealing. The sealant 9′ may only (a) fill (i) a space between the liquid crystal driver 3 and the film base member 2 and (ii) a space between the interposer substrate 4a and the film substrate 2, and (b) cover an edge surface that is a side surface of the interposer substrate 4a.

Here, the sealant 9′ may be the same as the sealant 9 shown in FIG. 2. However, the sealant 9′ can be a different kind from the sealant 9. For example, the sealant 9 can employ a sealant having a low viscosity in order to seal only a part that has connection with fine pitch bumps, at which part resin cannot flow smoothly. An example of such a sealant 9 is resin that has a viscosity of approximately 0.5 Pa·s and is used in resin sealing of a COF. On the other hand, the sealant 9′ may employ a sealant having a high viscosity. An example of such a sealant 9′ is resin which has a viscosity of approximately 1.5 Pa·s and is used in resin sealing of a TCP (Tape Carrier Package). By employing a sealant having a high viscosity, it becomes possible to prevent the sealant 9′ from flowing into the device hole 8.

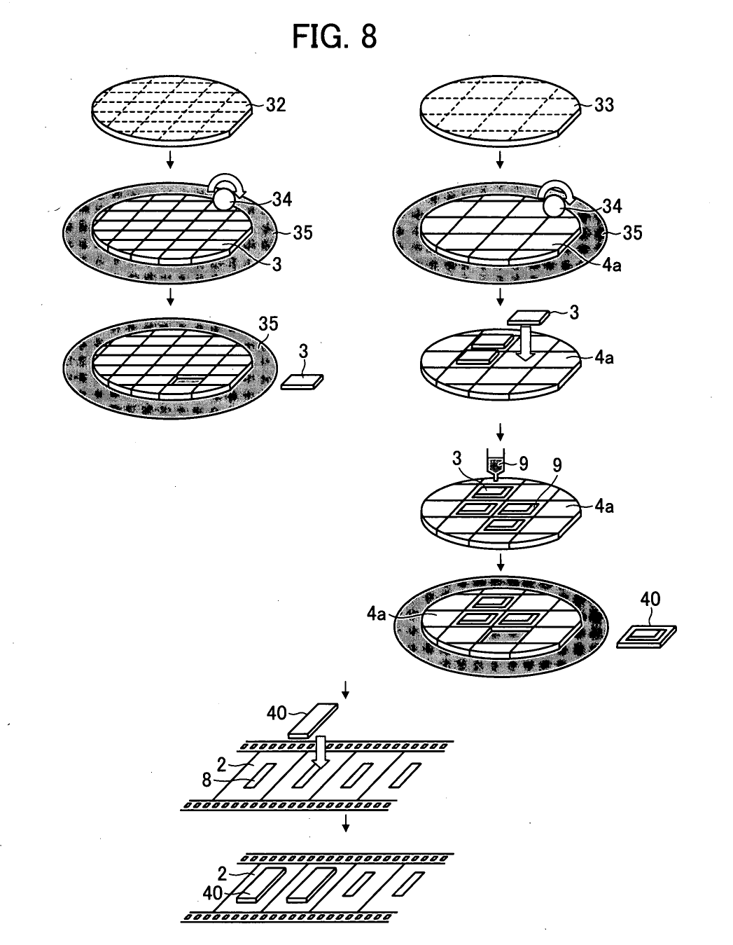

In the method mentioned above, the sealant 9 mainly seals parts which are subjected to the ACF/ACP bonding. However, the present invention is not limited to this. As illustrated in FIG. 7, the sealant 9′ may be provided so as to cover the liquid crystal driver 3. This makes it possible to protect the liquid crystal driver 3 and the parts which are subjected to the ACF/ACP bonding.

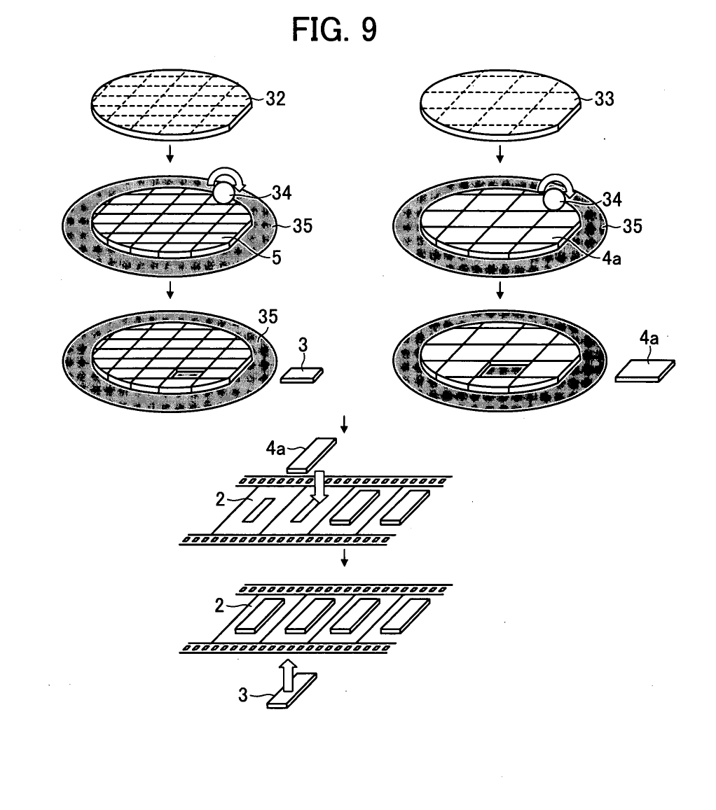

The aforesaid production method of the liquid crystal driver package 1a is merely one example. The present invention is not limited to this method. The production method may employ methods illustrated in FIGS. 8 and 9 below.

FIG. 8 illustrates a state in which the interposer wafer 33 is diced before connected with the liquid crystal driver. Specifically, as illustrated in the drawing (a) surrounded by the dotted line in FIG. 5, the driver wafer 32 is mounted on a mounting platform 35, and diced by a dicing blade 34 into individual chips having a predetermined chip size. Concurrently, dicing of the interposer wafer 33 is started as illustrated in the drawing (b) surrounded by the dotted line in FIG. 5. When a groove 36 is formed on the interposer wafer 33, the dicing is once stopped and an insulating material that forms an insulating film 7 is applied as mentioned above. After the application of the insulating material, dicing is resumed. As a result, the interposer wafer 33 is separated into individual interposer substrates 4a.

The individual liquid crystal driver 3 and the individual interposer substrate 4a are thus obtained. The liquid crystal driver 3 is connected to the interposer substrate 4a to obtain the liquid crystal driver mounted interposer substrate 40. Then, as mentioned above, this liquid crystal driver mounted interposer substrate 40 is connected to the film base member 2. As a result, the liquid crystal driver package 1a can be obtained.

FIG. 9 illustrates a state in which the liquid crystal driver 3 and the interposer substrate 4a are connected on the film base member 2. In other words, as with FIG. 8, the liquid crystal driver 3 and the interposer substrate 4a on which the insulating film 7 is provided are produced, separately. The film base member connecting terminals 13 of the interposer substrate 4a are connected to the on-film wires 5 and 6 on the liquid crystal driver package 1a with the use of an ACF or ACP. Then, the liquid crystal driver 3 is connected to the interposer substrate 4a mounted on the film base member 2. As a result, the liquid crystal driver package 1a can be obtained.

As mentioned above, in the liquid crystal driver package 1a of the present embodiment, the insulating film 7 is formed at a part where the on-film wires 5 and 6 each may touch an edge section of the interposer substrate 4a and/or on the periphery section of the edge section. With this arrangement, it is less likely that there occurs a short circuit in wires between the on-film wires 5 and 6 and the interposer substrate 4a. As a result, it becomes possible to provide a highly reliable liquid crystal driver package 1a even if a typical interposer substrate made of semiconductor such as silicon is employed.

Moreover, with the provision of the insulating film 7, the ACF bonding as mentioned above can be adopted without difficulty. Thus, it is possible to reduce cost for package production while realizing a package of a desired quality for the following reasons. That is, because the ACF bonding is a process performed under a low temperature and simultaneously completes resin sealing and the bonding, it becomes possible to realize a short processing time and a high productivity. Moreover, since the ACF bonding eliminates the need for a protruding terminal as a connection terminal, a production process of the interposer substrate can be simplified.

In the present embodiment, the insulating film 7 is provided by application of an insulating material to the edge section of the interposer substrate 4a made of semiconductor substrate and the periphery section of the edge section. However, the present invention is not limited to this arrangement. Alternatively, the insulating film 7 may be provided by subjecting the end section of the interposer substrate 4a and the periphery section of the end section to oxidation treatment.

In the liquid crystal driver package of the present invention, the interposer substrate 4a may be made from an insulating material or a material that transmits visible light. With the arrangement in which the interposer substrate is wholly realized by an insulating substrate, it is possible to simplify the production process of the interposer substrate, as compared with the arrangement in which the insulating film 7 is provided only at the edge section of the interposer substrate 4a and the periphery section of the edge section.

Specific examples of such an insulating substrate are ceramics, glass epoxy, silicon dioxide, and sapphire. Among these materials, glass epoxy, silicon dioxide, and sapphire particularly have a property of transmitting visible light. In the case of flip chip bonding, the liquid crystal driver 3 is bonded to the interposer substrate so that a surface having the terminals 3a and 3b of the liquid crystal driver 3 faces a surface having the liquid crystal driver connecting terminals 12 of the interposer substrate. In this case, the terminals 3a and 3b and the liquid crystal driver connecting terminals 12 are sandwiched between the liquid crystal driver and the interposer substrate and cannot be seen externally. Therefore, it becomes difficult for a producer to check a bonding (connecting) condition of these terminals. On the contrary, the interposer substrate made of a material having a property of transmitting visible light allows a producer or an apparatus capable of checking the connecting condition to check the connecting condition easily.

Moreover, the present invention may replace the interposer substrate 4a by an interposer substrate 4b. The interposer substrate 4b includes a multilayer wire 14′ of multilayer structure.

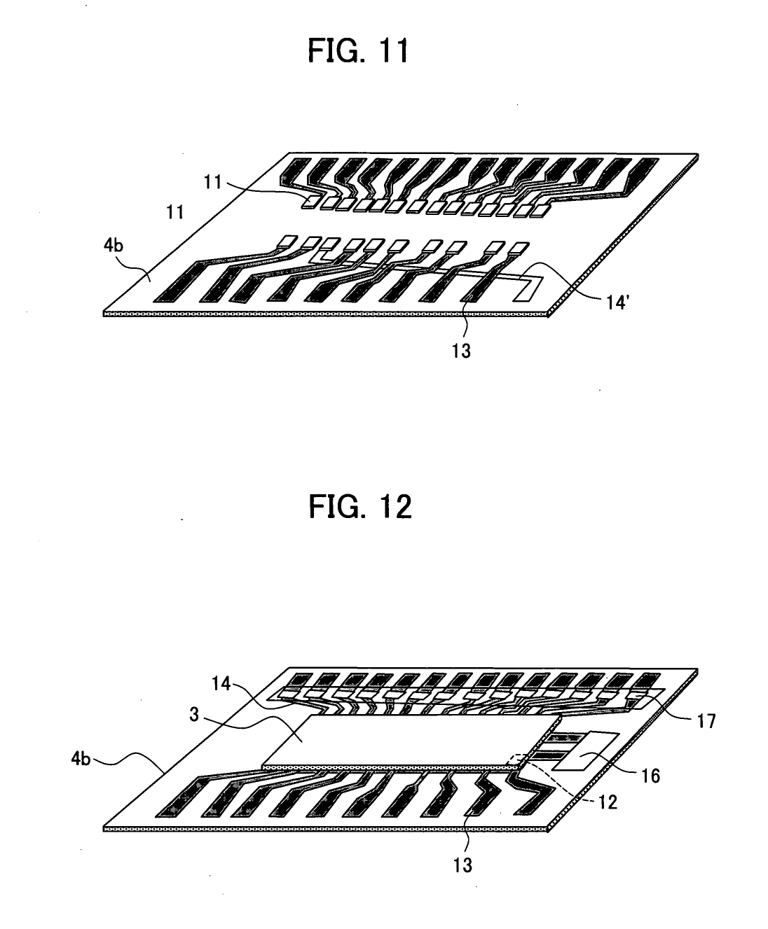

When on-substrate wires disposed on an interposer substrate have a single layer structure, a terminal order of the film base member connecting terminals 13 has to be the same as a terminal order of the liquid crystal driver connecting terminals 12. However, multilayer wires such as the multilayer wire 14′ makes it possible to cross wires as shown in FIG. 11. Therefore, the terminal order of the film base member connecting terminals 13 can be arranged to be different from the terminal order of the liquid crystal driver connecting terminals 12.

For example, in mounting the liquid crystal driver package on a liquid crystal display, input-end terminals of the liquid crystal driver may need to be changed according to a type of the liquid crystal display. In this case, the liquid crystal driver itself needs to be changed if the liquid crystal driver is directly connected to the film base member. However, in an arrangement where the liquid crystal driver package includes the interposer substrate 4b as illustrated in FIG. 11, it becomes possible to change an order of wires on the interposer substrate 4b. Because the interposer substrate 4b can be produced in a semiconductor process as mentioned above and eliminates the need for a fine process, which is necessary for the production of the liquid crystal driver 3. Consequently, the production cost can be suppressed, compared with the production cost in a case where the liquid crystal driver itself is changed.

The liquid crystal driver package 1a of the present embodiment may be provided with an interposer substrate 4b including the following components other than the multilayer wires 14′.

The interposer substrate 4b as illustrated in FIG. 12 includes a power source circuit (power source element) 16, and output drive buffers (output buffer elements) 17 in addition to the liquid crystal driver connecting terminals 12, the film base member connecting terminals 13, and the on-substrate wires 14.

The liquid crystal driver 3 and the interposer substrate 4b are produced in separate processes as explained in Embodiment 1. The interposer substrate 4b can be produced by, for example, a process by which the power supply circuit 16 is readily fabricable so as to supply the voltage generated by the power supply circuit 16 on the interposer substrate 4b to the liquid crystal driver 3.

The liquid crystal driver for the liquid crystal panel needs to have a sufficient driving capability in view of the load determined by the size and other factors of the liquid crystal display to which the driver is mounted. An unnecessarily large capability would however result in an excessively large liquid crystal driver. The problem is addressed by mounting the output drive buffers 17 as shown with the interposer substrate 4b in FIG. 12. Various liquid crystal displays can be driven by changing the size of the output drive buffers 17 in accordance with the liquid crystal displays, while the driving capability of the liquid crystal driver 3 is kept at low levels. The approach also reduces cost for the liquid crystal driver 3.

In FIG. 12, the output drive buffers 17 are mounted on the interposer substrate 4b in an equal number to the outputs. All the output drive buffers 17, corresponding to all the outputs, may be mounted on the interposer substrate 4b. Alternatively, some of the buffers 17, corresponding to some of the outputs, may be mounted on the interposer substrate 4b. Moreover, output operational amplifiers for the liquid crystal driver 3 may be provided on the interposer substrate 4b so that the entire liquid crystal drive voltage output circuitry, including the output drive buffers 17 for all the outputs, can be placed on the interposer substrate 4b. The structure enables the operational amplifiers and all other analog circuits to be placed on the interposer substrate 4b, leaving only logic circuitry inside the liquid crystal driver 3. That can greatly reduce the chip area of the liquid crystal driver 3. Although the structure increases the cost of the interposer substrate 4b, the increase is less than the cost saving for the liquid crystal driver 3 if the interposer substrate 4b is manufactured with an inexpensive process. The overall cost goes down.

FIG. 12 shows the interposer substrate 4b including the output drive buffers 17. The interposer substrate 4b may include input buffers. That would reduce the cost for the liquid crystal driver. In addition, signal inputs to the liquid crystal driver are often produced by FPDS, RSDS, LVDS, or other display interface technology based on differential signals. The technology requires that a standard compliant receiver be built into the liquid crystal driver. The driver can readily operate with interfaces of different standards if the input buffers and receivers are provided on the semiconductor substrate.

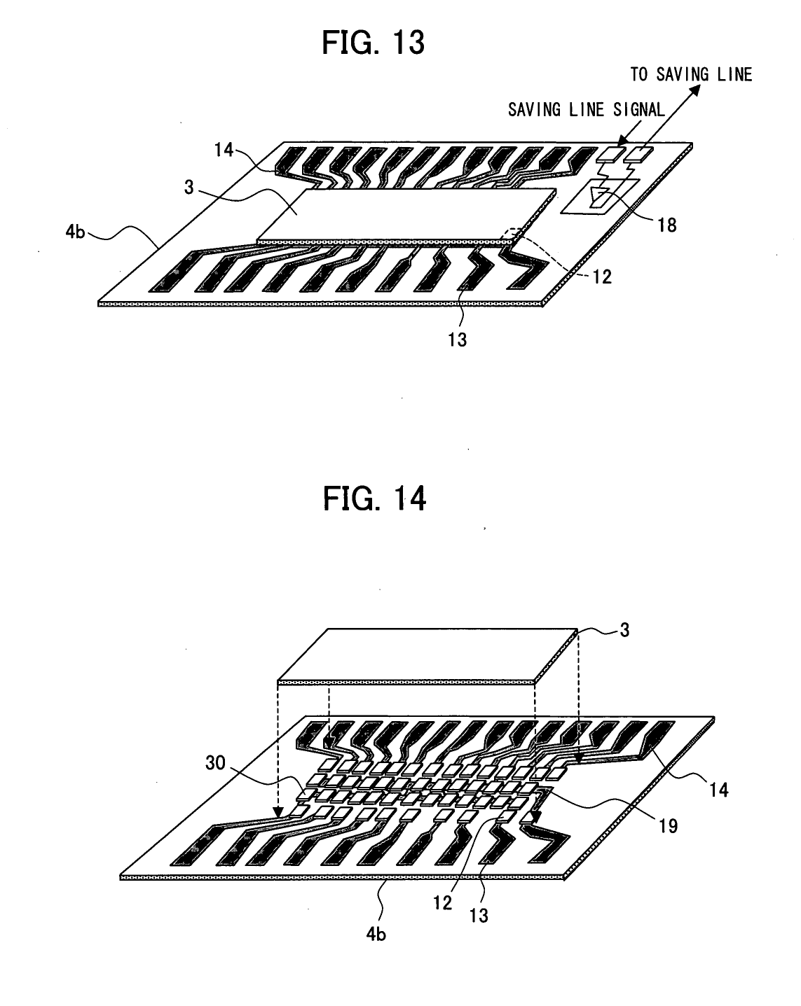

The interposer substrate 4b illustrated in FIG. 13 includes a redundant buffer (redundant buffer element) 18, as well as the liquid crystal driver connecting terminals 12, the film base member connecting terminals 13, and the on-substrate wires 14.

If a wire to a pixel in the liquid crystal display is cut off in the middle, the cut-off wire does not properly turn on. To prevent this from happening, a solution is known which saves by feeding drive signals from the other end of the cut-off wire. The solution adds to the load due to the connection of signal lines and other factors, requiring drive buffers with larger-than-usual driving capability. The mounting of the large redundant buffer to the liquid crystal driver which is produced by a fine process is costly. Accordingly, the redundant buffer 18 is mounted to the interposer substrate 4b. The structure minimizes cost increases of the interposer substrate 4b and prevents cost increase of the liquid crystal driver 3.

The interposer substrate 4b illustrated in FIG. 14 includes a common power supply wire 19 and a common GND wire (common ground wire) 30, as well as the liquid crystal driver connecting terminals 12, the film base member connecting terminals 13, and the on-substrate wires 14.

The liquid crystal driver 3 has many output circuits and uses analog circuits. If the power supply impedance differs from one output to another, output voltages differ (deviation between outputs). To reduce the differences, typically, multilayer wires need to be used in the liquid crystal driver to provide a power supply wire with a large width. However, the provision of a power supply wire adds another layer to the wire layer, a potential cause for cost increase. Accordingly, the interposer substrate 4b illustrated in FIG. 14 has common wires (common power supply wire 19 and common GND wire 30) and pads and terminals which connect the outputs of the liquid crystal driver 3 to the common wire. The provision of these members allows the omission of the power supply wires from the liquid crystal driver 3 and reduces differences in power supply impedance between outputs from the liquid crystal driver 3. The deviations between outputs of the liquid crystal driver 3 are lowered. Display quality is improved.

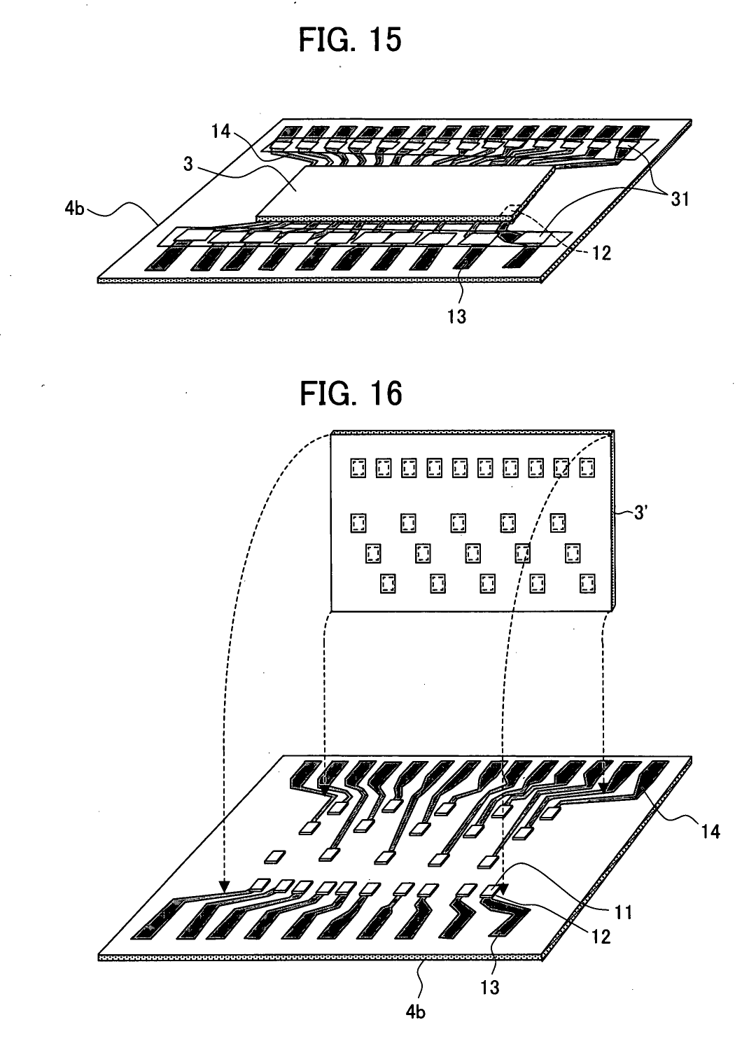

The interposer substrate 4b as illustrated in FIG. 15 includes a protective element 31, as well as the liquid crystal driver connecting terminals 12, the film base member connecting terminals 13, and the on-substrate wires 14.

The protective element 31 is a circuit which provides protection from electrostatic discharge (ESD). Electrostatic discharge is thought to have several modes. In one mode, a machine or a worker at an assembly line could charge and later discharge to an integrated circuit. In another mode, a package for an integrated circuit could charge and later discharge to the outside. In any of the modes, the electrostatic discharge could be as high as thousands of volts and destroy integrated circuits. Especially, charge in the former mode and accompanying ESD-caused destruction is likely in a step of mounting the liquid crystal driver package 1a to the liquid crystal panel. To prevent ESD-caused destruction, the protective element 31 needs to have high voltage tolerance. This is an obstacle in reducing the size of the protective element 31 even when the internal circuitry of the protective element 31 is highly integrated. In order to solve this problem, as illustrated in FIG. 15, the protective element 31 is mounted to the interposer substrate 4b. This makes it possible to manufacture the liquid crystal driver 3 only by a fine process. Consequently, higher integration of the liquid crystal driver 3 becomes possible. Moreover reduction in cost can be also realized by reducing chip size. Meanwhile, the interposer substrate 4b can be manufactured without using the fine process, which is used for production of the liquid crystal driver 3. Accordingly, mounting the protective element 31 to the interposer substrate 4b is less costly than mounting the protective element to the liquid crystal driver.

The present embodiment has so far described structures which include one of multi-layered wires, output drive buffers, input buffers, a power supply circuit, a redundant buffer, a common power supply wire, a common GND wire, and a protective element. The present invention is by no means limited to these structures.

The interposer substrate 4b in the present embodiment also may have an arrangement as illustrated in FIG. 16.

FIG. 16 illustrates the structures of an interposer substrate 4b and the liquid crystal driver. A liquid crystal driver 3′ as illustrated in FIG. 16 has its terminal pads provided all over the liquid crystal driver surface and the interposer substrate 4b has its liquid crystal driver connecting terminals 12 and second bumps 11 provided at positions corresponding to the terminal pads.

The structure eases restrictions in positioning the output circuit (not shown) of the liquid crystal driver 3′. The liquid crystal driver 3′ as a result resembles a square, rather than a rectangle which is the case in FIG. 5.

Integrated circuits, including liquid crystal drivers, are produced in multiple numbers on a circular wafer as mentioned above. To obtain more chips from a single wafer, square chips have an advantage. With the use of the liquid crystal drive 3′, the shape of the liquid crystal driver becomes a squarish shape. As a result, the manufacturing cost of the liquid crystal driver 3′ can be reduced.

Alternatively, the squarish shape of the liquid crystal driver can be achieved by building the on-substrate wires 14 to have a multilayer structure.

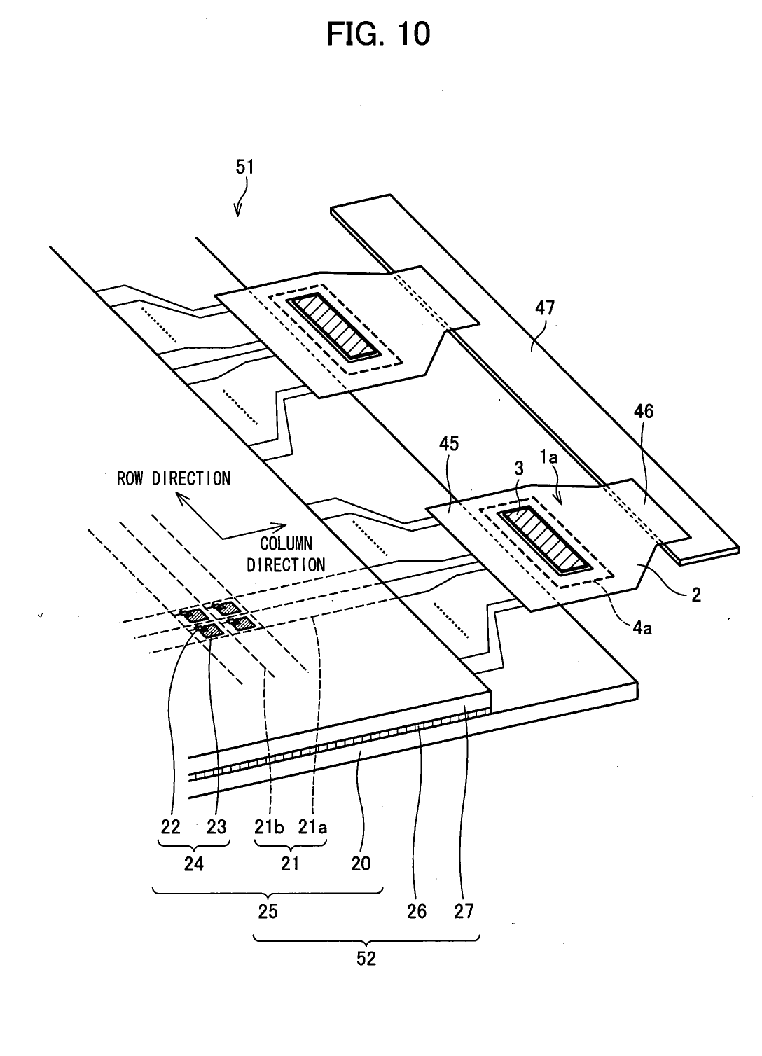

Next, with reference to FIG. 10, explained is a liquid crystal driver mounted display apparatus (image display apparatus) including the liquid crystal driver packages 1a of the present embodiment.

FIG. 10 is an oblique view showing the structure of a liquid crystal driver mounted display apparatus which is an embodiment of the present invention. The liquid crystal driver mounted display apparatus 51 of the present embodiment includes, as shown in FIG. 10, a liquid crystal display means (image display) 52, and liquid crystal driver packages 1a. In the liquid crystal driver package 1a, a liquid crystal driver 3 is mounted to a tape carrier 2 through the interposer substrate 4a. In the liquid crystal driver package 1a, the tape carrier 2 is provided with an output terminal section 45 and an input terminal section 46.

The liquid crystal display means 52 includes an active matrix substrate 25, a liquid crystal layer 26, and an opposite substrate 27 on which an opposite electrode is formed.

The active matrix substrate 25 includes, as shown in FIG. 10, a glass substrate 20 which carries on it signal wires 21, and pixels 24. Each pixel 24 is made of a thin film transistor (hereinafter, referred to as “TFT”) 22, a pixel electrode 23, and others. The pixels 24 are arranged in an XY matrix (two-dimensional matrix). The data electrode and gate electrode of the TFT 22 are connected to a data electrode line 21a and a gate electrode line 21b, respectively.

The data electrode lines 21a and gate electrode lines 21b extend along the column and row directions respectively on the active matrix substrate 25. The electrode lines 21a and 21b are respectively connected at an edge of the glass substrate 20 to a plurality of the liquid crystal drivers that drive the respective electrode lines. For convenience, the following explanation is given to only an arrangement of the data electrode lines 21a shown in FIG. 10. However, it is obvious that the gate electrode lines 21b can be similarly arranged.

The data electrode lines 21a are extended to an edge of the glass substrate 20. At the edge, the data electrode lines 21a are connected to drive signal output terminals provided in the output terminal section 45 of the liquid crystal driver package 1a. The drive signal output terminals are formed at a predetermined pitch in the output terminal section 45, and a plurality of the data electrode lines are formed at the edge section of the glass substrate 20 at the same pitch as the pitch of the drive signal output terminals. The connection between the drive signal output terminals and the data electrode lines can be realized, for example, by subjecting the drive signal output terminals and the data electrode lines to thermo compression with the drive signal output terminals and the data electrode lines overlapped one another via an ACF.

The signal input terminals provided in the input terminal section 46 of the liquid crystal driver package 1a are connected to the wires provided on an external wiring substrate 47. The wires on the external wiring substrate 47 supply control signals such as display data and a power source voltage, which are transmitted to the liquid crystal driver 3 through the tape carrier 2 and the interposer substrate 4a.

The liquid crystal driver 3 generates drive signals in accordance with the display data and outputs the drive signals to the drive signal output terminals of the liquid crystal driver package 1a through the interposer substrate 4a. Accordingly, the drive signals are transmitted to the data electrode lines 21a and lightning of the corresponding pixels can be controlled.

As mentioned above, the liquid crystal driver package 1a of the present invention is such that in mounting the liquid crystal driver 3 having terminals provided at a fine pitch for increased number of outputs or miniaturization, the interposition of the interposer substrate 4a makes it possible to change the terminal pitch of the liquid crystal driver 3 to a larger pitch, without deterioration of reliability. This eliminates the need for a significant change of a wiring pitch of the film base member (tape carrier) in the existing technique. Consequently, the liquid crystal driver mounted display apparatus can be assembled without change of the existing assembly process. As a result, it becomes possible to realize higher performance or cost reduction of the liquid crystal driver mounted display apparatus, while ensuring sufficient reliability.

In the present embodiment, the active matrix substrate 25 contains the glass substrate 20. This is by no means limiting the present invention. Conventional, publicly known substrates may be used so long as they are transparent.

The present embodiment deals with the liquid crystal driver 3 as a driver of the data electrode lines. This is by no means limiting the present invention. The invention may be applied to the liquid crystal driver for the gate electrode lines.

The present embodiment has so far described a liquid crystal driver package that drives a liquid crystal display. This is by no means limiting the IC chip package of the present invention. The invention is equally applicable to a package for mounting a driving element of an EL (electroluminescence) display and a package for mounting an element to be incorporated in an apparatus such as various mobile electronic apparatuses.

The IC driver package of the present invention can be restated as being characterized by the following features.

Namely, the IC driver package includes an IC chip, an interposer substrate on which the IC chip is mounted, and a tape carrier connected to the interposer substrate, wherein: the interposer substrate includes terminals connected to the tape carrier on a surface identical to a surface where the IC chip is mounted; an insulating property is provided at least on a surface of the interposer substrate and an edge of the surface of the interposer substrate at a position where the tape carrier and the interposer substrate overlap each other; and the interposer substrate and the tape carrier are connected to each other with an ACF (Anisotropic Conductive Film).

### Embodiment 2

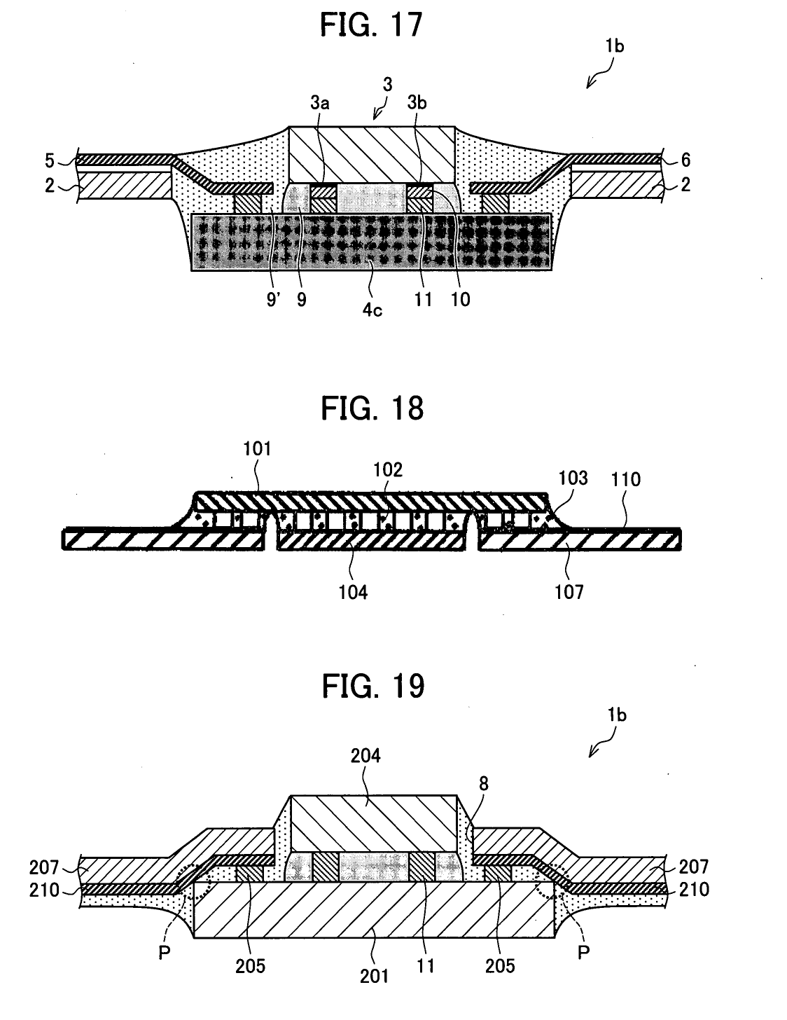

The following will describe another embodiment of the present invention in reference to FIG. 17. The embodiment will focus on differences from embodiment 1. For convenience, members of the present embodiment that have the same arrangement and function as members of embodiment 1, and that are mentioned in that embodiment are indicated by the same reference numerals and description thereof is omitted.

FIG. 17 is a cross sectional diagram illustrating an arrangement of a liquid crystal driver package 1b of the present embodiment. The present embodiment shows an example of a liquid crystal driver package in the form of a TCP. In this liquid crystal driver package 1b, wiring conductors formed on an interposer substrate 4c is arranged to face a surface of a film base member 2 opposite to a surface on which on-film wires 5 and 6 are formed.

The liquid crystal driver package 1b includes a tape carrier composed of a film base member 2 on which the on-film wires 5 and 6 are formed, the interposer substrate 4c made of an insulating material, and a liquid crystal driver 3. The liquid crystal driver 3 is connected to the interposer substrate 4c by bumps 10 and 11. In the form of a TCP, as illustrated in FIG. 17, the on-film wires 5 and 6 are formed so as to protrude into a through hole (device hole) formed on the film base member 2 and serve as inner leads. The interposer substrate 4c is connected with an anisotropic conductive adhesive to the inner leads.

In this way, the inner leads made of the on-film wires 5 and 6 face and overlap the interposer substrate 4c even in the TCP, in which a surface of the film base member 2 opposite to the surface on which the on-film wires 5 and 6 are formed is arranged to face wiring conductors formed on the interposer substrate 4c. Therefore, the present invention having an arrangement in which the interposer substrate is made of an insulating material is advantageous for prevention of a short circuit between the on-film wires 5 and 6.

The embodiment shown in FIG. 17 describes a case where the interposer substrate 4c is made of an insulating material. However, the same effect can be obtained in an arrangement in which an interposer substrate has an insulating section at an edge section of the substrate. Moreover, as with the aforesaid embodiment 1, the present embodiment 2 can be effectively applied to an image display apparatus as illustrated in FIG. 10.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. An IC chip package comprising:
an IC chip;
an interposer substrate including wiring conductors each having an IC chip connecting terminal and a tape carrier connecting terminal; and
a tape carrier including wiring conductors each having an interposer substrate connecting terminal to be connected to the tape carrier connecting terminal by conductive connection, wherein:
the tape carrier connecting terminal is connected with an anisotropic conductive adhesive to the interposer substrate connecting terminal to form conductive connection; and
the interposer substrate has an insulating section at an edge section thereof.

2. The IC chip package as set forth in claim 1, wherein
the tape carrier is made of a flexible material.

3. The IC chip package as set forth in claim 1, wherein
the insulating section is provided in a region on a surface of the interposer substrate, which region faces the wiring conductors of the tape carrier.

4. The IC chip package as set forth in claim 1, wherein
an insulating film is provided as the insulating section.

5. The IC chip package as set forth in claim 1, wherein
the interposer substrate is an insulating substrate.

6. The IC chip package as set forth in claim 1, wherein
the interposer substrate is made of a material having a property of transmitting visible light.

7. The IC chip package as set forth in claim 1, wherein
the anisotropic conductive adhesive is an anisotropic film obtained by forming thermosetting resin in which conductive particles are mixed so that the thermosetting resin is in film form, or an anisotropic conductive paste obtained by forming thermosetting resin in which conductive particles are mixed so that the thermosetting resin is in paste form.

8. An IC chip package comprising:
an IC chip;
an interposer substrate including wiring conductors each having an IC chip connecting terminal and a tape carrier connecting terminal; and
a tape carrier including wiring conductors each having an interposer substrate connecting terminal to be connected to the tape carrier connecting terminal by conductive connection, wherein:
the interposer substrate is a semiconductor substrate; and
the interposer substrate has an insulating section at an edge section thereof.

9. The IC chip package as set forth in claim 1, wherein
the IC chip is a driver IC for driving an image display that operates under an electrical signal.

10. The IC chip package as set forth in claim 8, wherein
the IC chip is a driver IC for driving an image display that operates under an electrical signal.

11. An image forming apparatus comprising an IC chip package and an image display that operates under an electrical signal, wherein:
the IC chip package includes:
an IC chip;
an interposer substrate including wiring conductors each having an IC chip connecting terminal and a tape carrier connecting terminal; and
a tape carrier including wiring conductors each having an interposer substrate connecting terminal to be connected to the tape carrier connecting terminal by conductive connection, wherein:
the tape carrier connecting terminal is connected with an anisotropic conductive adhesive to the interposer substrate connecting terminal to form conductive connection;
the interposer substrate has an insulating section at an edge section thereof; and
the IC chip is a driver IC for driving an image display that operates under an electrical signal.

12. An image forming apparatus comprising an IC chip package and an image display that operates in accordance with an electrical signal, wherein:
the IC chip package includes:
an IC chip;
an interposer substrate including wiring conductors each having an IC chip connecting terminal and a tape carrier connecting terminal; and
a tape carrier including wiring conductors each having an interposer substrate connecting terminal to be connected to the tape carrier connecting terminal by conductive connection, wherein:
the interposer substrate is a semiconductor substrate;
the interposer substrate has an insulating section at an edge section thereof; and
the IC chip is a driver IC for driving an image display that operates under an electrical signal.
